(19) United States
(12) Patent Application Publication
(10) Pub. No.: US 2003/0002271 A1
(43) Pub. Date: Jan. 2, 2003

(54) Integrated EMC shield for integrated circuits and multiple chip modules

(75) Inventor: Janne Nurminen, Oulu (FI)

Correspondence Address: COHEN, PONTANI, LIEBERMAN & PAVANE, Suite 1210, 551 Fifth Avenue, New York, NY, 10176, US

(73) Assignee: Nokia Corporation

(21) Appl. No.: 09/894,350

(22) Filed: Jun. 27, 2001

(51) Int. Cl. H05K 9/00; H05K 3/30

(52) U.S. Cl. 361/818; 29/832; 29/841; 361/807

(57) ABSTRACT

A semiconductor package has a die connected to a substrate with a transfer molding applied over the die. The transfer molding includes an electrically conductive material for forming an electromagnetic compatibility shield as an integral part thereof.

### BACKGROUND OF THE INVENTION

1. Field of the Invention

The present invention relates to a semiconductor package including a die arranged on a substrate and a transfer molding having an integrated electromagnetic compatibility (EMC) shield for integrated circuits and for multiple chip modules, and to a method for manufacturing the semiconductor package with the integrated EMC shield.

2. Description of the Related Art

Known semiconductor packages which include a die or multiple dies, such as an integrated circuit (IC) or a multiple chip module (MCM), are encased in a transfer molding made of an insulating or dielectric material as disclosed in U.S. Pat. No. 6,087,202. The semiconductor package is a unit that is installed on a printed circuit board (PCB) with other components as part of a larger device. If a particular application of the known semiconductor package requires an EMC shield, a separate EMC shield is arranged around the semiconductor package on the PCB. This requires additional space on the PCB and adds a workstep during assembly of the PCB.

### SUMMARY OF THE INVENTION

The present invention includes a semiconductor package, an integrated circuit (IC) or a multiple chip module (MCM) connected to a substrate in any known manner. The semiconductor package includes one die on the substrate surrounded by a transfer molding. In contrast to the prior art, at least a part of a transfer molding of the semiconductor package includes a conductive material for forming an EMC shield as an integral part of the transfer molding. The conductive material is connectable to ground via a GND pin of the semiconductor package. Accordingly, the EMC shield is arranged as an integral part of the sermiconductor package itself during manufacture of the semiconductor package.

If the die of the semiconductor package is wire bonded to the substrate, the transfer molding includes an insulating material and an over molding including the conductive material. The insulating material is first applied on the die for electrical and mechanical protection of the wires. The over molding, including the conductive material, is then applied over the insulating material.

If the die of the semiconductor package is a flip chip, the insulating material is not necessary and the transfer molding contains only the conductive material applied directly on the die, without the insulating material.

For both embodiments, an outer insulating layer may be optionally applied over the conductive material.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

In the drawings, wherein like reference characters denote similar elements throughout the several views:

FIG. 1 is a sectional side view of a semiconductor package according to an embodiment of the present invention;

FIG. 2 is a sectional side view of a semiconductor package according to another embodiment of the present invention;

FIGS. 3a-3g are sectional views showing various stages of the manufacturing process for the semiconductor package of FIG. 1;

FIG. 4a-4e are sectional views showing various stages of the manufacturing process for the semiconductor package of FIG. 2; and

FIG. 5 is a sectional side view of a semiconductor package including a plurality of dies.

### DETAILED DESCRIPTION OF THE PRESENTLY PREFERRED EMBODIMENTS

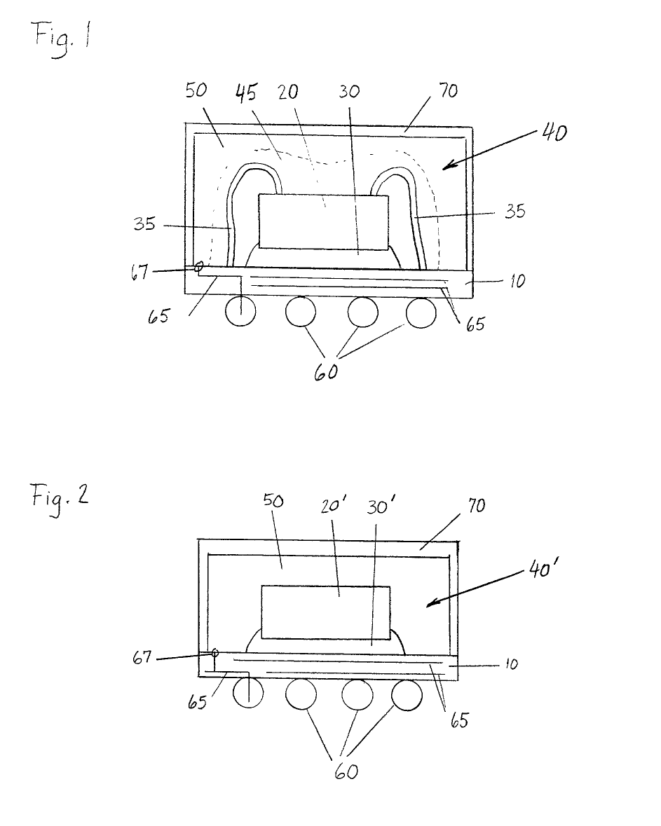

FIG. 1 discloses a semiconductor package according to a first embodiment of the present invention. The semiconductor package includes a printed circuit board (PCB) 10 on which a die 20, i.e., a semiconductor chip, is arranged. The PCB 10 includes routing wires 65 which are arranged under a mask (not shown). The die 20 comprises a wire bonded die in that the die 20 is electrically connected to routing wires 65 of the PCB 10 via wires 35. The die 20 is physically attached or held onto the PCB 10 by a connection 30 which may, for example, comprise glue or solder.

A transfer molding 40 encapsulates the die 20 on the PCB 10. The transfer molding 40 includes a non-conductive material 45 which encapsulates the wires 35 and the die 20 on the PCB 10, and a conductive material 50 that covers the non-conductive material 45 and provides an electromagnetic compatibility (EMC) shield for the die 20. The non-conductive material 45 may comprise a non-conductive material such, for example, as an insulating epoxy. The conductive material may comprise any conductive material and may, for example, comprise electrically conductive fillers added to an insulating epoxy. The thickness of the conductive material 50 will depend on the amount of shielding required; an increase in the thickness of the conductive material increases the protection and effectiveness of the EMC shield. In addition, the concentration of electrically conductive fillers that are added to the insulating epoxy may be varied to adjust the strength of the EMC shield.

Connectors such as solder balls 60 are arranged on the PCB 10 for interconnection of the semiconductor package in a larger circuit. Of course any other known connectors such as pins or glue may also be used. One of the solder balls 60 is designated as a ground connection and the conductive material 50 of the transfer molding 40 is connected to that grounding solder ball 60 via one of the routing wires 65 through the PCB 10. The mask covering the routing wires 65 has an opening in the area 67 where the conductive material 50 is connected to the grounding (GND) of the routing wire 65.

The transfer molding 40 may be applied using any known molding method, including injection molding, transfer molding, and glop top molding. The layers of conductive material 50 and non-conductive material 45 of the transfer molding 40 may be applied as a liquid, a gel, a two component epoxy, a paste, or a sheet. Furthermore, the hardening or setting of the transfer molding may be effected using any known method such, for example, as applied infrared light, heating/cooling, physical/chemical reaction, and the application of pressure.

In a preferred embodiment, the non-conductive material 45 is a hot epoxy applied via injection molding and hardened or set via a cooling process. The conductive material 50 is also a hot epoxy with electrically conductive fillers added thereto to create a conductive material and is likewise applied via injection molding and hardened or set as the epoxy cools. The epoxy used to make the conductive material 50 may be the same epoxy used for the non-conductive material 45, or a different material.

The transfer molding 40 may also include an insulation layer 70 that is applied over the conductive material 50 for electrical protection. The insulation layer 70 may be formed of the same materials as the non-conductive material 45, or of a different material.

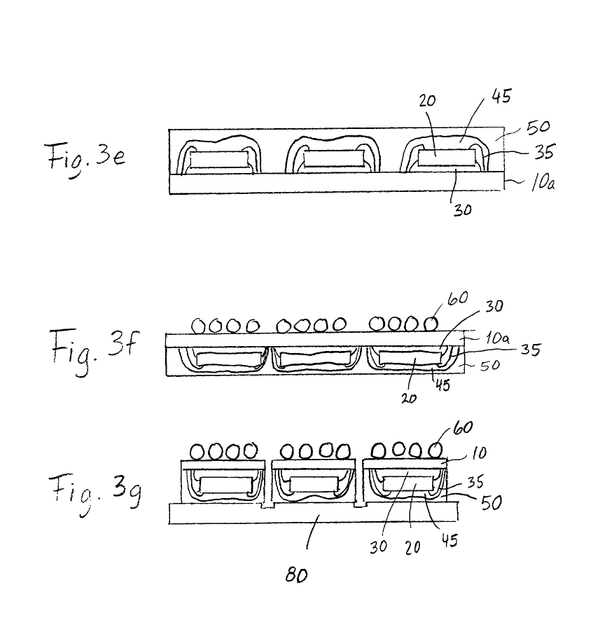

The process for making the semiconductor package shown in FIG. 1 is depicted in FIGS. 3a-3g. A plurality of semiconductor packages are concurrently formed on a PCB matrix strip 10a, as shown in FIG. 3a. The PCB matrix strip 10a is a continuous strip provided for receiving a plurality of dies 20 and is separable into plural sections to form the individual PCBs 10. In FIG. 3b, the plurality of dies 20 are arranged face up on the PCB matrix strip 10a and are attached thereto via a connection 30 such, for example, as via glue or solder. In FIG. 3c, each die 20 is then electrically connected to the PCB matrix strip 10a via wire bonding; that is, wires 35 are connected between each die 20 and the underlying section of the PCB matrix strip 10a. After the wires 35 are attached, a non-conductive material 45 is applied over each die 20 and the wires 35 associated with that die 20 for electrical and mechanical protection of the die, as shown in FIG. 3d. The non-conductive material 45 may comprise any non-conductive material and preferably comprises an insulating epoxy. As stated above, the non-conductive material is preferably applied as a hot epoxy by injection molding and hardened via a cooling period.

A layer of conductive material 50 is then applied over the non-conductive material 45 on each of the dies 20 to provide the EMC shield (FIG. 3e). The conductive material 50 may comprise any type of conductive material and preferably comprises electrically conductive fillers added to an insulating epoxy to create a conductive material. The conductive material 50 is also preferably applied as a hot epoxy by injection molding and hardened through cooling. The conductive material 50 is connected to a ground pin of the semiconductor package via a wire 65 through the PCB matrix strip 10a (see FIG. 1). The solder balls 60 are arranged on the PCB matrix strip 10a for eventual connection of the sermiconductor package to a circuit as shown in FIG. 3f. The PCB matrix strip 10a with the plurality of dies 20 is placed on a support 80 and each semiconductor package is then separated from the rest, as via sawing, to form the individual semiconductor packages (FIG. 3g.).

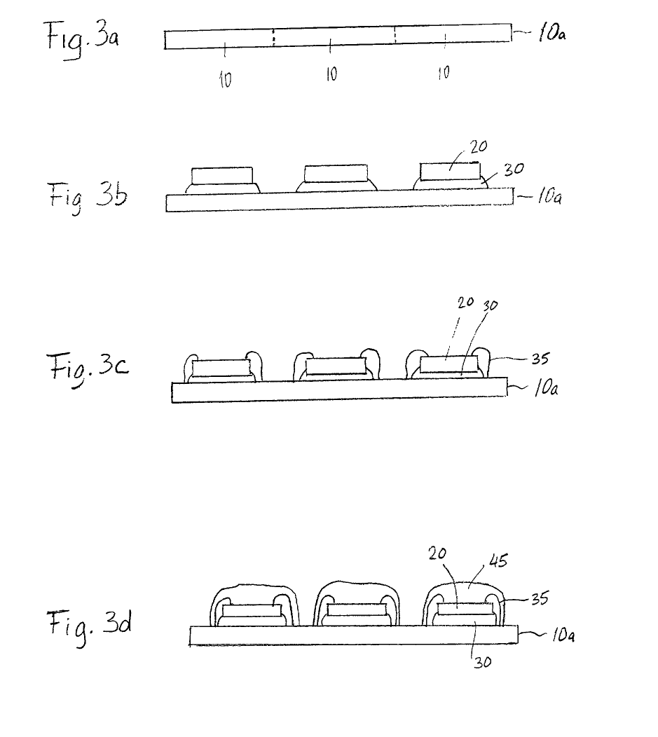

FIG. 2 depicts a further embodiment in which the die 20′ is a flip chip which is connected face down to the PCB 10. The electrical connection between the die 20′ and the routing wires 65 is made via solder bumps during reflow (the solder bumps cannot be seen in FIG. 2). An underfill 30′ comprising a protection material is applied so that it covers and protects the soldering between the die 20′ and PCB 10. The protection material may comprise any insulating material and may, for example, comprise the insulating epoxy described above for the non-conductive material 45 of FIG. 1. In FIG. 2, the transfer molding 40′ comprises only a conductive material 50 as described above. The non-conductive material 45 of the embodiment of FIG. 1 is not required because the underfill 30′ and the mask over the routing wires 65 protect the electrical connection between the die 20′ and the PCB 10. As in the previous embodiment, the mask has an opening at the area 67 for the connection between the conductive material 50 and the GND routing wire 65.

This FIG. 2 embodiment may also optionally include an insulation layer 70 applied over the conductive material 50 for electrical protection.

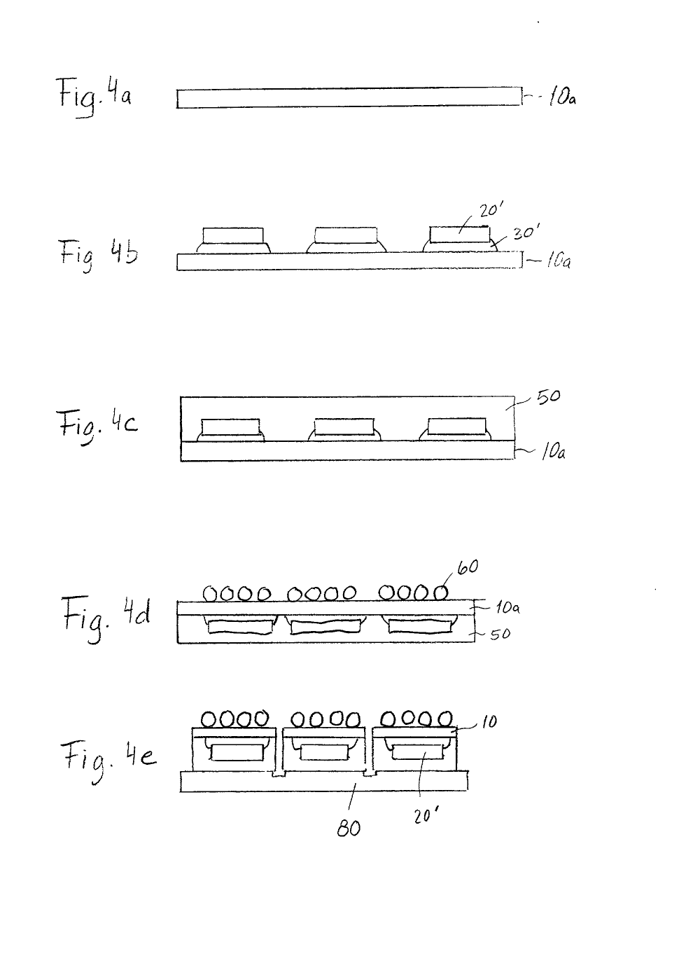

The process for making the semiconductor package of FIG. 2 is shown in FIGS. 4a-4e.

As seen in FIG. 4a, PCB matrix strip 10a is provided for holding a plurality of dies 20′. The plural dies 20′ are then arranged face down on the PCB matrix strip 10a and electrically and mechanically attached via solder bumps (not shown). After the dies are soldered to the PCB matrix, an underfill comprising a non-conductive protective material 30′ is applied between the die 20′ and the PCB matrix 10a to provide mechanical and electrical protection to the solder, as shown in FIG. 4b. A layer of conductive material 50 is next applied over each die and the underfill material to provide the EMC shield shown in FIG. 4c. As in the embodiment of FIG. 1, the conductive to provide the EMC shield shown in FIG. 4c. As in the embodiment of FIG. 1, the conductive material 50 may comprise any type of conductive material and preferably comprises electrically conductive fillers added to an insulating epoxy. The conductive material 50 is also preferably applied as a hot epoxy by injection molding and hardened by cooling. The conductive material 50 is connected to a ground pin of the semiconductor package via a wire through the PCB matrix 10a (see FIG. 2). FIG. 4d shows the solder balls 60 arranged on the PCB matrix 10a for connection of the semiconductor package to a circuit. The entire PCB matrix 10a and all dies 20′ thereon are then placed on a support 80 and each semiconductor package is separated from the rest, as by sawing, to form the individual semiconductor packages, as shown in FIG. 4e.

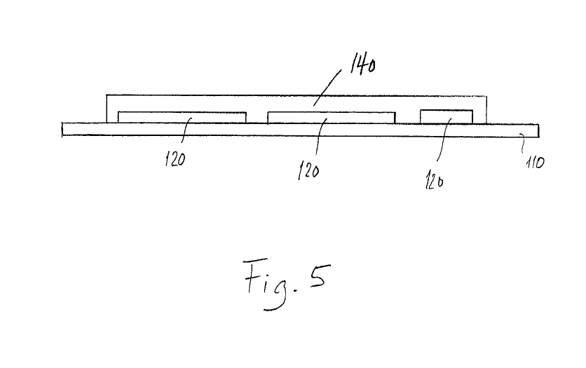

Each of the embodiments of the invention depicted in FIGS. 1 and 2 comprise a semiconductor package having a single die. However, the semiconductor package may instead comprise a Multiple Chip Module (MCM) having more than one die as shown in FIG. 5. In the FIG. 5 embodiment, a transfer molding 140 is shown arranged over three dies 120 on a PCB 110. The dies 120 may be flip chip devices or wire bound devices or a mixture of the two. The transfer molding may include only a conductive material—i.e., may exclude the non conductive material 45 of the FIG. 1 embodiment—if the dies are flip chip devices. Furthermore, the transfer molding 140 may include either one large insulating layer covering all of the dies 120 or individual insulating layers over only those dies 120 that are wire bonded devices.

Thus, while there have shown and described and pointed out fundamental novel features of the invention as applied to preferred embodiments thereof, it will be understood that various omissions and substitutions and changes in the form and details of the methods and devices described and illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. An electronic device, comprising:
a substrate;
a die arranged on said substrate; and
a transfer molding encapsulating said die on said substrate, wherein said transfer molding comprises a conductive material to form an electromagnetic compatibility shield.

2. The device of claim 1, wherein said transfer molding comprises a first portion and a second portion, said first portion comprising an insulating material and said second portion comprising said conductive material.

3. The device of claim 2, wherein said die comprises a wire bond device arranged face up on said substrate and wires connecting said die to said substrate, said first portion of said transfer molding encapsulating at least said wires, and said second portion being arranged on said first portion.

4. The device of claim 2, wherein said first portion of said transfer molding is applied directly on said device and said second portion is arranged on said first portion.

5. The device of claim 2, wherein said first portion comprises an insulating epoxy applied by injection molding and said second portion comprises an insulating epoxy with electrically conducting filler material and applied by injection molding.

6. The device of claim 1, wherein said die comprises a flip chip device arranged face down on said substrate and wherein said conductive material of said transfer molding is applied directly on said die.

7. The device of claim 1, wherein said substrate comprises a GND pin for connection of said device to a ground of a printed circuit board, said conductive material of said transfer molding being electrically connected to said GND pin.

8. The device of claim 1, wherein said conductive material includes an electrically conductive filler added to an insulating epoxy.

9. The device of claim 1, wherein said die comprises an integrated circuit.

10. The device of claim 1, further comprising a plurality of dies, wherein said transfer molding is applied over each of said plural dies.

11. The device of claim 1, further comprising an insulating layer applied over said transfer molding.

12. A method for manufacturing an electronic device, comprising the steps of:
(a) connecting a die to a substrate; and
(b) applying over said die a transfer molding comprising a conductive material, the conductive material forming an electromagnetic compatibility shield as an integral part of the transfer molding.

13. The method of claim 12, wherein said step (b) comprises applying a transfer molding including a first portion and a second portion of the transfer molding, the first portion comprising an insulating material and the second portion comprising a conductive material.

14. The method of claim 13, wherein the die is a wire bonded device having wires connecting the die to the substrate, and said wherein step (b) comprises applying the first portion on the die such that the first portion covers at least the wires and applying the second portion on the first portion.

15. The method of claim 13, wherein said step (b) comprises applying the first portion of the transfer molding directly on the die and applying the second portion of the transfer molding on said first portion.

16. The method of claim 13, wherein said step of applying said transfer molding includes the steps of applying the first portion as a hot insulating epoxy and hardening the applied first portion by cooling the hot insulating epoxy of the first portion, and applying the second portion as a hot insulating epoxy including electrically conductive filler so that the second portion is electrically conductive and hardening the applied second portion by cooling the hot insulating epoxy of the second portion.

17. The method of claim 12, wherein the die is a flip chip device and said step (b) comprises applying the conductive material directly on the die.

18. The method of claim 12, further comprising the step of connecting the conductive material to a GND pin of the substrate.

19. The method of claim 12, wherein said step (b) comprises applying said transfer molding as a hot epoxy and hardening the applied transfer molding by cooling of the hot epoxy.

20. The method of claim 12, wherein the semiconductor package is one of an integrated circuit and a multiple chip module.
